(19) United States
(12) Patent Application Publication
(10) Pub. No.: US 2012/0019124 A1
(43) Pub. Date: Jan. 26, 2012

(54) ELECTROLUMINESCENT DEVICE AND SEGMENTED ILLUMINATION DEVICE

(75) Inventor: Dirk Hente, Wuerselen (DE)

(73) Assignee: KONINKLIJKE PHILIPS ELECTRONICS N.V., EINDHOVEN (NL)

(21) Appl. No.: 13/259,477

(22) PCT Filed: Mar. 18, 2010
(86) PCT No.: PCT/IB2010/051169

§ 371 Date: Sep. 23, 2011

(30) Foreign Application Priority Data
Mar. 26, 2009 (EP) 09156310.6

(51) Int. Cl. H05B 33/02

(52) U.S. Cl. 313/498

(57) ABSTRACT

The present invention relates to an electroluminescent device comprising:
first electroluminescent layer (102; 102′, 102″, . . . ), a first electrode layer (104; 104′, 104″, . . . ) arranged on a first side of the electroluminescent layer and a second electrode layer (106; 106′, 106″, . . . ) arranged on a second side, opposing the first side of the electroluminescent layer, for supplying charges to the electroluminescent layer, the first electrode layer consisting of an opaque material and the second electrode layer consisting of a transparent material,
a single first contact element (108) for contacting the first electrode layer with a charge supply, and a single second contact element (114) for contacting the second electrode layer with the charge supply,
   wherein the first contact element extends along a first edge (110) of the first electrode layer, wherein the second contact element extends along a second edge (115) of the second electrode layer, wherein the first and second edges are parallel to each other,
   the first electrode layer having a first square resistance, and the second electrode layer having a second square resistance, the first square resistance being from 0.1 to 3 times the second square resistance.

### FIELD OF THE INVENTION

The present invention relates to the field of electroluminescent devices, and more particularly to organic light emitting diode (OLED) devices, and to the field of segmented illumination devices.

### BACKGROUND OF THE INVENTION

Electroluminescent devices comprise electroluminescent material that is capable of emitting light when a current is passed through it. The material used for electroluminescent devices can be light emitting polymers or small organic molecules. Organic devices may, for example be organic light emitting diodes (OLEDs), which are known in the art. For activating the electroluminescent devices, current is applied to the electroluminescent material by means of the electrodes disposed at surfaces of the electroluminescent material.

Electroluminescent devices, such as OLEDs, comprise electroluminescent material disposed between electrodes. Upon application of a suitable voltage, current flows through the electroluminescent material from anode to cathode. Light is produced by radiative recombination of holes and electrons inside the electroluminescent material.

Electroluminescent devices using organic electroluminescent material are suitable for large area lighting applications such as, for instance, general illumination. It is known to use a plurality of electroluminescent devices, combined into a tiled area having a large lighting area.

The size of single electroluminescent devices can be several square centimeters and the size of a tiled area can be a plurality thereof. The electroluminescent devices are suitable to create flat direct-view luminaries used for general lighting, as well as for effect light, and atmosphere lighting.

For instance, for general lighting, the electroluminescent devices have ring-shaped electrodes arranged to accomplish an approximately uniform distribution of light emission over the whole electroluminescent surface.

In contrast, strip-form prior art OLEDs show a significant brightness drop along the current flow direction especially at high currents. Typically, the variation of the luminance of strip-form OLEDs is above 50% in the direction of the current flow.

The invention therefore aims to provide an improved electroluminescent device, especially an improved OLED device, and an improved segmented illumination device.

### SUMMARY OF THE INVENTION

The present invention provides an electroluminescent device as claimed in claim 1 and a segmented illumination device as claimed in the claim 13. Embodiments of the invention are given in the dependent claims.

In accordance with embodiments of the invention an electroluminescent device is provided that has a first electroluminescent layer being interposed between a first electrode layer and a second electrode layer. The first electrode layer is arranged on a first side of the first electroluminescent layer and the second electrode layer is arranged on the second side of the first electroluminescent layer. The second side is opposite to the first side of the first electroluminescent layer. The first and second electrode layers are arranged for supplying charges to the electroluminescent layer, i.e. the first electrode layer constituting a cathode and the second electrode layer constituting the anode of the electroluminescent device. The first electrode layer consists of an opaque material, such as a metal, and the second electrode layer consists of a transparent material. Hence, the second electrode layer constitutes the transparent conductive (TCO) layer of the electroluminescent device. For example, the second electrode layer can consist of indium tin oxide (ITO).

In accordance with embodiments of the invention the first electrode layer consists of aluminum, silver or a metal alloy.

The electroluminescent device further comprises a single first contact element for contacting the first electrode layer with a charge supply and a single second contact element for contacting the second electrode layer with the charge supply. The first contact element extends along a first edge of the first electrode layer and the second contact element extends along a second edge of the second electrode layer, wherein the first and second edges are parallel to each other. The first and second edges are spaced apart in the width direction of the electroluminescent device whereas the first and second contact elements extend along a length direction of the electroluminescent device.

The first electrode layer has a first square resistance and the second electrode layer have a second square resistance, the first square resistance being from 0.1 to 3 times the second square resistance. This is in contrast to prior art electroluminescent devices where the square resistance of the opaque cathode is orders of magnitude below the high ohmic resistance of the transparent anode. Surprisingly, a high ohmic cathode that has a square resistance within the same order of magnitude as the anode provides an improved uniformity of the brightness of the electroluminescent device in the direction of the current flow without substantially impacting the power efficiency of the electroluminescent device.

This is particularly advantageous for lighting applications where both a uniform brightness and a high power efficiency of the electroluminescent device is desired.

In accordance with an embodiment of the invention, the first square resistance of the first electrode layer, i.e. the cathode, is from 0.9 to 1.1 times the second square resistance of the second electrode layer, i.e. the anode. Most preferably the first and second square resistances are substantially equal for maximum uniformity of the brightness of the electroluminescent device in the direction of the current flow.

In accordance with an embodiment of the invention, the first and second square resistances are within the range between 30 ohms and 100 ohms. For example, the first and second square resistances can be 50 ohms or 70 ohms.

In accordance with an embodiment of the invention, the first and second square resistances are selected such that the brightness, i.e. the luminance variation of the second electrode layer, is below 60% when the charge is supplied to the electroluminescent layer under normal operating conditions.

In accordance with an embodiment of the invention, the high ohmic first electrode layer provides a ballast resistor such that the electroluminescent device can be coupled directly to mains power without an external ballast resistor. The first and second square resistances are selected such that when mains power is applied the resulting luminance variation on the second electrode layer is below 53% or below 50% in the width direction of the electroluminescent device.

In accordance with an embodiment of the invention, the electroluminescent device has a strip-form with an aspect ratio of above 1 to 2, i.e. the length of the electroluminescent device is at least two times its width. This is particularly advantageous as the beneficial effect of using a high ohmic first electrode layer is especially striking for such strip-like electroluminescent devices.

In accordance with a further embodiment of the invention, the electroluminescent device has a second electroluminescent layer and a third electrode layer. The second electroluminescent layer is interposed between the first electrode layer and the third electrode layer, the first electrode layer constituting the cathode and the third electrode layer the anode for the second electroluminescent layer. The third electrode layer consists of a transparent material. The transparent material of which the third electrode layer is made may be the same or another transparent material of that of the second electrode layer. The third electrode layer has a third square resistance which may be identical to the second square resistance. The first square resistance is between 0.1 to 3 times the third square resistance, preferably between 0.9 to 1.1 times of the third square resistance. Most preferably, the first, second and third square resistances are substantially identical.

In accordance with an embodiment of the invention, the electrode layers and the two electroluminescent layers constitute a stacked electroluminescent device that emits light from both its front and back surfaces.

In another aspect the present invention relates to a segmented illumination device that comprises a plurality of electroluminescent devices. The electroluminescent devices may be connected in series. The resulting total resistance of the segmented illumination device constitutes a ballast such that the segmented illumination device can be directly connected to mains power without an additional ballast resistor. This is particularly advantageous as the power dissipation that is due to the ballast resistor is performed in a distributed way involving all the segments.

### BRIEF DESCRIPTION OF THE DRAWINGS

In the following embodiments of the invention are described in greater detail by way of example only making reference to the drawings in which:

FIG. 1 is a perspective view of an embodiment of an electroluminescent device in accordance with the invention,

FIG. 2 is a diagram illustrating the normalized current variation along the width direction of the electroluminescent device of FIG. 1,

FIG. 3 is a diagram being illustrative of the voltage drop in the width direction of the electroluminescent device of FIG. 1,

FIG. 4 is a cross-sectional view of an embodiment of a segmented illumination device in accordance with the invention having a dual stacked configuration of the individual segments,

FIG. 5 is a diagram being illustrative of the voltage drop in the width direction of one of the segments of the segmented illumination device of FIG. 4.

### DETAILED EMBODIMENTS

In the following the same reference numerals are used to designate like elements throughout the various embodiments described below.

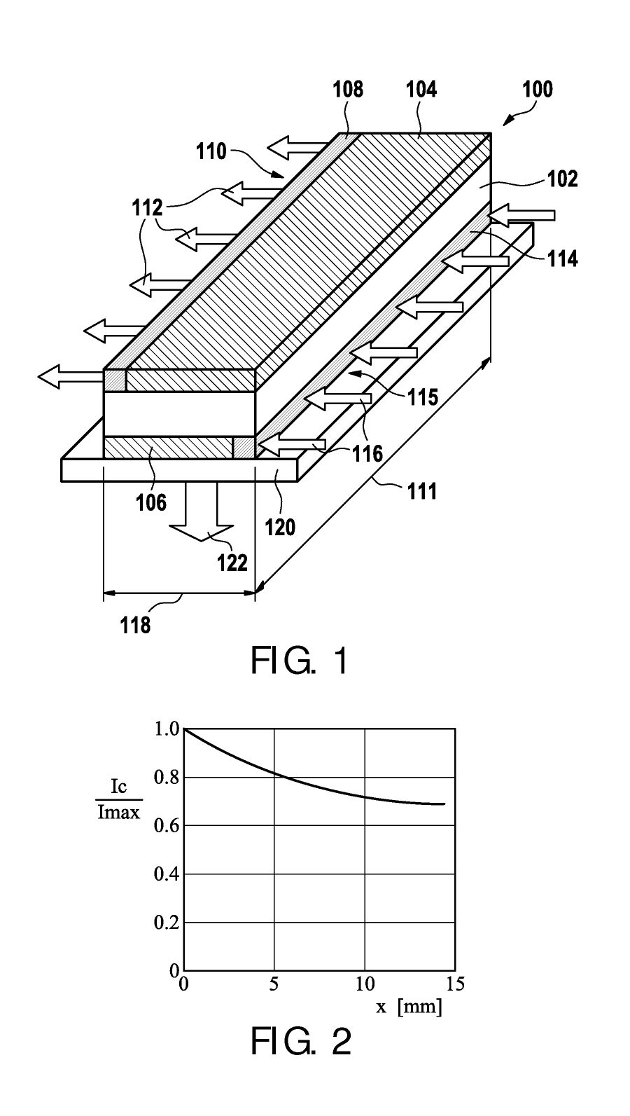

FIG. 1 shows an electroluminescent device 100. The electroluminescent device 100 has an electroluminescent layer 102. The electroluminescent layer 102 may comprise light emitting polymers or small organic molecules. In particular, the electroluminescent device 100 can be implemented as an OLED.

The electroluminescent device 100 has a first electrode layer 104 that constitutes the cathode. The electrode layer 104 is arranged on the topside of the electroluminescent layer 102. A second electrode layer 106 is arranged on the opposing bottom side of the electroluminescent layer 102. The electrode layer 106 constitutes the anode of the electroluminescent device 100.

The electrode layer 104 is in electrical contact with a first contact element 108. The first contact element 108 extends along a first edge 110 of the electroluminescent device 100 into the length direction 111 of the electroluminescent device 100. The contact element 108 can form an integral part of the electrode layer 104. Preferably, the contact element 108 is embedded within the electrode layer 104. The contact element 104 can consist of the same material as the electrode layer 104. The contact element 108 serves to receive an output current flow 112.

The electrode layer 106 is in electrical contact with a second contact element 114. The second contact element 114 extends along a second edge 115 of the electroluminescent device 100 into the length direction 111 of the electroluminescent device 100. The contact element 114 can form an integral part of the electrode layer 106. Preferably, the contact element 114 is embedded within the electrode layer 106. The contact element 106 can consist of the same material as the electrode layer 106. The contact element 114 serves to conduct input current flow 116. The contact elements 108 and 114 are spaced apart in the width direction 118 of the electroluminescent device 100 by the width of the electroluminescent device 100.

The electroluminescent device 100 can be arranged on a transparent substrate 120, such as glass.

In the embodiment considered here the electroluminescent device 100 is formed as a stripe with parallel edges 110 and 115. The electroluminescent device 100 has an aspect ratio of greater than 1 to 2, i.e. the length into which the electroluminescent device 100 extends into the length direction 111 is at least twice as big as the width by which the electroluminescent device 100 extends into the width direction 118.

The electrode layer 106 is a transparent conductive layer made of a transparent and conductive material such as ITO. The electrode layer 104 is opaque and can be reflective in order to reflect light that is emitted from the electroluminescent layer 102 when the current flows through the electroluminescent device such that charge is provided to the electroluminescent layer 102. The light 122 that is emitted from the electroluminescent layer 102 and which is reflected from the electrode layer 104 is emitted through the electrode layer 106 and the substrate 120 such as for illumination purposes.

The square resistance of the electrode layer 104 has the same order of magnitude as the square resistance of the electrode layer 106. Hence, both the opaque electrode layer 104 and the transparent electrode layer 106 have high ohmic square resistances. For example, the square resistance of the electrode layer 104 is between 0.1 to 3 times the square resistance of the electrode layer 106. Preferably, the square resistance of the electrode layer 104 and the square resistance of the electrode layer 106 are substantially equal. This is in contrast to prior art electroluminescent devices that have a cathode electrode layer having a square resistance being at least one order of magnitude below the square resistance of the anode electrode layer.

Surprisingly, the high ohmic cathode electrode layer 104 has a beneficial effect in terms of reducing the variation of the luminance of the electronic device 100, especially when the electronic device 100 is operated with a high current flow, without having a substantial impact on the power efficiency of the electronic device 100.

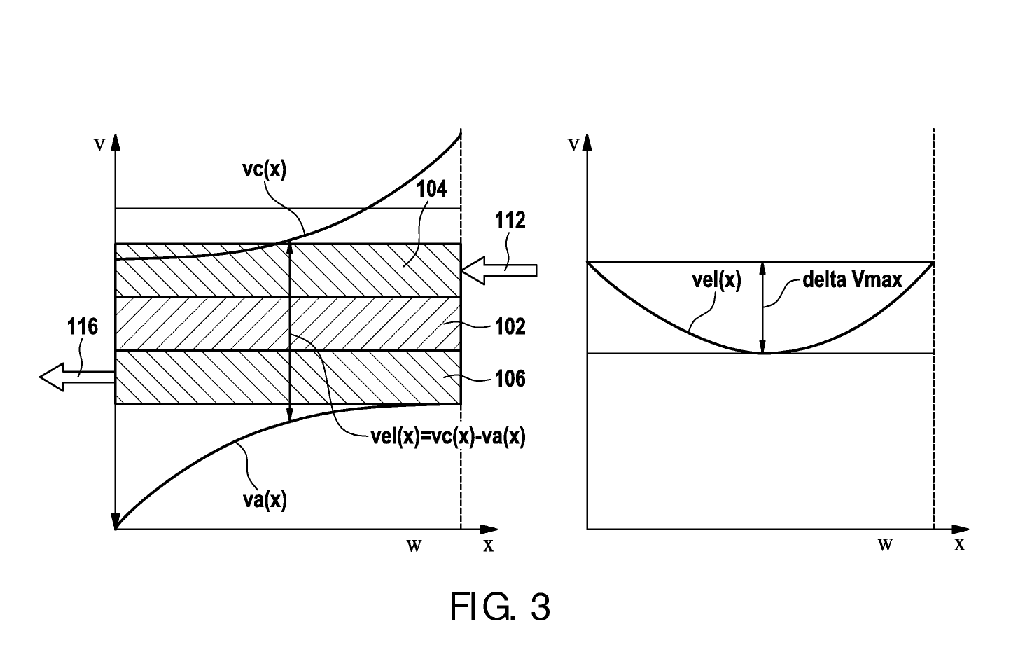

FIG. 2 illustrates the current density Ic of the current that flows through the electroluminescent layer 102 as a function of the width coordinate x that goes into the width direction 118 (cf. FIG. 1). The current flows through the electroluminescent layer 102 for supplying charges thereto. x=0 is at the edge 115 and x=15 mm is at the edge 110 of the electroluminescent device 100, i.e. the electroluminescent device 100 has a width of 15 mm in the example considered here. The current density Ic has been normalized with the maximum current density Imax that flows through the electroluminescent layer 102 at position x=0.

As can be seen from FIG. 2 the current I decreases by only 30% from the edge 115 to the edge 110 into the width direction 118 which corresponds to a variation of the luminance of the light 122 emitted through the second electrode layer 106 of also 30%. Such a relatively small variation of the luminance cannot be recognized by the naked human eye such that the illumination provided by the electroluminescent device 100 appears uniform over the entire surface of the electrode layer 106.

For example the square resistance of the electrode layer 104 and the square resistance of the electrode layer 106 are equal and have a value of 50 ohms. When the electroluminescent device 100 is driven by a current flow I of 0.1 A the luminance of the light 122 emitted by the electroluminescent device 100 varies between Lmax=2721 cd per square meter and L min=1944 cd per square meter with a power efficiency of 48.7 lm/W.

FIG. 3 illustrates the respective voltage drops along the width direction 118 of the electroluminescent device 100. In particular, FIG. 3 illustrates the cathode voltage vc, the anode voltage va and the emission layer voltage vel that is applied across the electroluminescent layer 102. The emission layer voltage vel is the difference between the cathode voltage vc and the anode voltage va.

Due to the high ohmic square resistance of the electrode layer 104 that is substantially equal to the square resistance of the electrode layer 106 the electroluminescent device 100 has a significant voltage drop both across the electrode layer 106 and the electrode layer 104. As the voltage drop increases over the width on the cathode side while it decreases on the anode side a partial cancellation takes place. The result is a reduced total voltage drop where the maximum voltage drop delta Vmax appears at the centre of the electroluminescent device 100. For symmetry reasons the cancellation is at a maximum if both square resistances of the electrode layer and the electrode layer 106 are the same.

The reduced voltage drop that is limited to delta Vmax implies a reduced current variation of the current I flowing through the electroluminescent layer 102 according to the current voltage characteristic of the electroluminescent layer 102. The resulting variation of the luminous intensity of the light 122 is proportionally reduced as well because of the essentially linear relation between current and luminous intensity.

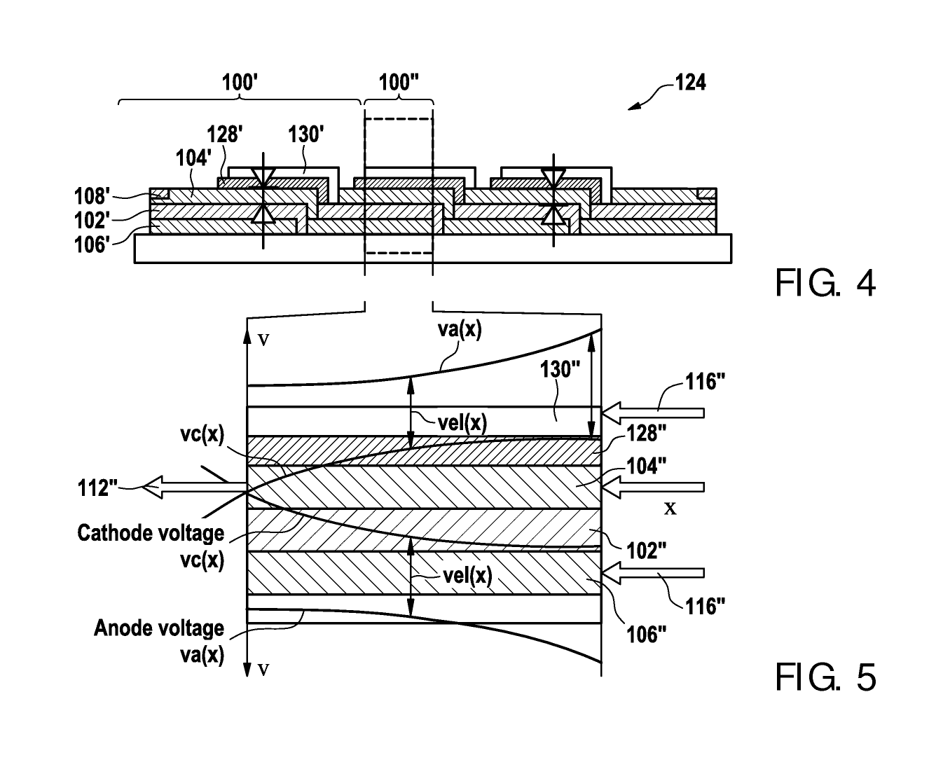

FIG. 4 shows a segmented illumination device 124, where each segment of the illumination device 124 is constituted by a dual stacked electroluminescent device. For example, the electroluminescent device 100′ has electrode layers 104′, 106′ and an electroluminescent layer 102′ that is interposed between the electrode layers 104′ and 106′ as it is the case for the electroluminescent device 100 of FIG. 1.

In the embodiment of FIG. 4 the electrode layer 104′ serves as a common cathode for an additional electroluminescent layer 128′ that is interposed between the electrode layer 104′ and an additional electrode layer 130′. The electrode layer 130′ can be made of the same material as the electrode layer 106′ and can have the same square resistance as the electrode layer 106′ and/or the electrode layer 104′. The electrode layer 130′ serves as an additional anode for the electroluminescent layer 128′. This way a dual stacked configuration of the electroluminescent device 100′ is provided. The electroluminescent device 100′ is connected in series with the neighboring electroluminescent device 100″ that constitutes the next segment of the illumination device 124.

FIG. 5 illustrates the voltages along the width direction of the electroluminescent device 100″. As illustrated in FIG. 5 a voltage drop compensation takes place simultaneously in both of the OLED devices that constitute the stacked electroluminescent device 100″. FIG. 5 shows the voltage drops over x when the square resistances of the cathode electrode layer 104″ and the square resistance of both of the anode electrode layers 106″ and 128″ are identical.

Embodiments of the electroluminescent device 100 are particularly advantageous as the resulting resistance of the high ohmic electrode layers 104′, 104″, . . . can be used as a ballast resistor for directly coupling the electroluminescent device 100 to mains power.

For example, a ballast resistance of 14 ohms can be integrated into the electroluminescent device 100 by selecting a square resistance of 70 ohms for both the electrode layer 104 and the electrode layer 106 when the aspect ratio is 1:10.

In accordance with a further embodiment of the invention, the resulting resistance of the serially connected electrode layers of a segmented illumination device constitutes such a ballast resistance that enables direct connection of the illumination device to mains power without an additional ballast resistor. For example, 65 segments of the type shown in FIG. 4 can be serially connected which results in a total ballast resistance of 910 ohms if the square resistance of the anode and cathode electrode layers is 70 ohms yielding the total resistance of 14 ohms per segment.

### LIST OF REFERENCE NUMERALS

100 electroluminescent device
100′ electroluminescent device
100″ electroluminescent device
102 electroluminescent layer
102′ electroluminescent layer
102″ electroluminescent layer
104 electrode layer
104′ electrode layer
104″ electrode layer
106 electrode layer
106′ electrode layer
106″ electrode layer
108 contact element
108′ contact element
110 edge
111 length direction
112 output current flow
112″ output current flow
114 contact element
115 edge
116 input current flow
116″ input current flow
118 width direction
120 substrate
122 light
124 illumination device
128′ electroluminescent layer
130′ electrode layer

1. An electroluminescent device comprising:
first electroluminescent layer, a first electrode layer arranged on a first side of the electroluminescent layer and a second electrode layer arranged on a second side, opposing the first side of the electroluminescent layer, for supplying charges to the electroluminescent layer, the first electrode layer comprising an opaque material and the second electrode layer comprising a transparent material,
a single first contact element for contacting the first electrode layer with a charge supply, and a single second contact element for contacting the second electrode layer with the charge supply,
wherein the first contact element extends along a first edge of the first electrode layer, wherein the second contact element extends along a second edge of the second electrode layer, wherein the first and second edges are parallel to each other,
the first electrode layer having a first square resistance, and the second electrode layer having a second square resistance, the first square resistance being from 0.1 to 3 times the second square resistance.

2. The electroluminescent device of claim 1, the first square resistance being from 0.9 to 1.1 times the second square resistance.

3. The electroluminescent device of claim 1, the first square resistance being substantially equal to the second square resistance.

4. The electroluminescent device of claim 1, wherein the electrode layers constitute a resistive ballast for directly connecting the electroluminescent device to a power source, the first and second square resistances being preferably between 30 ohms and 100 ohms

5. The electroluminescent device of claim 1, the first and second square resistances being 50 ohms or 70 ohms.

6. The electroluminescent device of claim 1, the first and second square resistances being selected such that the luminance variation on the second electrode layer is below 60% when the charge is supplied to the electroluminescent layer.

7. The electroluminescent device of claim 1, the electroluminescent device having a strip-form, the strip-form having an aspect ratio of greater than 1 to 2, wherein the first and second contact elements extend along the length of the strip-form.

8. The electroluminescent device of claim 1, further comprising a second electroluminescent layer, a first side of the second electroluminescent layer being arranged on the first electrode layer and a third electrode layer being arranged on a second side of the second electroluminescent layer, the second side of the second electroluminescent layer opposing the first side of the second electroluminescent layer, the third electrode layer having a third square resistance, the first square resistance being from 0.1 to 3 times the third square resistance.

9. The electroluminescent device of claim 8, the first square resistance being from 0.9 to 1.1 times the third square resistance.

10. The electroluminescent device of claim 8, the first, second and third square resistances being substantially equal.

11. The electroluminescent device of claim 8 being a stacked device sharing a common electrode.

12. The electroluminescent device of claim 1, wherein the first electroluminescent layer comprises an OLED device.

13. A segmented illumination device comprising a plurality of the electroluminescent devices of claim 1.

14. The segmented illumination device of claim 13, the electroluminescent devices being electrically coupled in a series connection.

15. The segmented illumination device of claim 13, the first electrode layers constituting a distributed ballast for directly connecting the segmented illumination device to mains power.
